(19) United States
(12) Patent Application Publication
(10) Pub. No.: US 2006/0205219 A1
(43) Pub. Date: Sep. 14, 2006

(54) Compositions and methods for chemical mechanical polishing interlevel dielectric layers

(76) Inventors: Arthur Richard Baker III, Deephaven, MN (US); Sarah J. Lane, Elkton, MD (US); Zhendong Liu, Newark, DE (US)

Correspondence Address: ROHM AND HAAS ELECTRONIC MATERIALS;CMP HOLDINGS, INC., 451 BELLEVUE ROAD, NEWARK, DE, 19713, US

(21) Appl. No.: 11/357,538

(22) Filed: Feb. 16, 2006

Related U.S. Application Data
(60) Provisional application No. 60/659,834, filed on Mar. 8, 2005.

(51) Int. Cl. C09K 13/00; B44C 1/22; H01L 21/302

(52) U.S. Cl. 438/692; 252/79.1; 252/79.4; 216/88

(57) ABSTRACT

The present invention provides an aqueous composition useful for polishing dielectric layers on a semiconductor wafer in interlevel dielectric processes comprising by weight percent 0.001 to 1 quaternary ammonium compound, 0.01 to 20 colloidal silica, 0 to 5 surfactant, 0 to 5 carboxylic acid polymer, and balance water.

This application claims the benefit of U.S. Provisional Application Ser. No. 60/659,834 filed Mar. 8, 2005.

### BACKGROUND OF THE INVENTION

The invention relates to chemical mechanical planarization (CMP) of semiconductor wafer materials and, more particularly, to CMP compositions and methods for polishing dielectric layers from semiconductor structures in interlevel dielectric (ILD) processes.

Modern integrated circuits are manufactured by an elaborate process where electronic circuits composed of semiconductor devices are integrally formed on a small semiconductor structure. The conventional semiconductor devices that are formed on the semiconductor structure include capacitors, resistors, transistors, diodes, and the like. In advanced manufacturing of integrated circuits, hundreds of thousands of these semiconductor devices are formed on a single semiconductor structure.

Additionally, integrated circuits may be arranged as adjoining dies on a common silicon substrate of the semiconductor structure. Typically, surface level scribe regions are located between the dies, where the dies will be cut apart to form discrete integrated circuits. Within the dies, the surface of the semiconductor structure is characterized by raised regions that are caused by the formation of the semiconductor devices. These raised regions form arrays and are separated by lower regions of lesser height in the form of slots on the silicon substrate of the semiconductor structure.

Conventionally, the semiconductor devices of the semiconductor structure are formed by alternately depositing and patterning layers of conducting and insulating material on the surface of the semiconductor structure. Frequently, in preparation for the deposition of successive layers, the surface of the semiconductor structure is required to be rendered smooth and flat. Thus, in order to prepare the surface of the semiconductor structure for a material deposition operation, a planarization process is required to be conducted on the surface of semiconductor structure.

Planarization is typically implemented by growing or depositing an interlevel dielectric layer of insulating material such as an oxide or nitride on the semiconductor structure, to fill in rough or discontinuous areas (e.g., slots). Interlevel dielectric layers are deposited as a conformal film, causing it to have a non-planar surface characterized by vertically raised protruding features of a greater height extending upward above the arrays and by open troughs of a lower height located above the slots. The planarization process is used to reduce the height of the vertically protruding features down to a target height that is typically a predefined distance above the level of the tops of the arrays where, ideally, a planarized surface will be formed.

Currently, CMP is the foremost technique to achieve the desired flatness or planarization. CMP enhances the removal of surface material, mechanically abrading the surface while a chemical composition (“slurry”) selectively attacks the surface. A conventional CMP slurry for ILD processes comprises a large concentration of abrasives (e.g., >than 30%) to enhance its effectiveness. Unfortunately, the abrasives are extremely expensive and increased use of the abrasives becomes cost prohibitive.

For example, U.S. Pat. No. 5,391,258 of Brancaleoni, et al. discusses a process for enhancing the polishing rate of silicon, silica or silicon-containing articles including composites of metals and silica. The composition includes about 33 weight percent alumina to enhance the removal rate for the dielectric layer. The composition also includes an oxidizing agent along with an anion that suppresses the rate of removal of the relatively soft silica thin film. The suppressing anion may be any of a number of carboxylic acids.

Hence, what is needed is a composition and method for chemical-mechanical polishing of dielectric layers having improved removal rates and reduced concentrations of abrasives. In particular, what is needed is a composition and method for polishing of dielectric layers in ILD processes, having improved removal rates and reduced concentrations of abrasives, as well as improved planarization efficiency.

### STATEMENT OF THE INVENTION

In one aspect, the present invention provides an aqueous composition useful for polishing dielectric layers on a semiconductor wafer in interlevel dielectric processes comprising by weight percent 0.001 to 1 quaternary ammonium compound, 0.01 to 20 colloidal silica, 0 to 5 surfactant, 0 to 5 carboxylic acid polymer, and balance water.

In another aspect, the present invention provides an aqueous composition useful for polishing dielectric layers on a semiconductor wafer in interlevel dielectric processes comprising by weight percent 0.001 to 1 tetrabutyl ammonium hydroxide, 0.01 to 20 colloidal silica, 0 to 5 surfactant, 0 to 5 polyacrylic acid and balance water, wherein the composition has a pH of 2 to 5.

In another aspect, the present invention provides a method for polishing dielectric layers on a semiconductor wafer in interlevel dielectric processes comprising: contacting dielectric layers on the wafer with a polishing composition, the polishing composition comprising by weight percent 0.001 to 1 quaternary ammonium compound, 0.01 to 20 colloidal silica, 0 to 5 surfactant, 0 to 5 carboxylic acid polymer, and balance water; and polishing the dielectric layers with a polishing pad.

### DETAILED DESCRIPTION OF THE INVENTION

The composition and method provide unexpected removal of dielectric layers and planarization efficiency with decreased concentration of abrasives. In particular, the composition comprises a quaternary ammonium compound to enhance the removal of the dielectric layer for ILD processes, at the pH of the application.

By way of example only, dielectric materials such as Boron-Phosphorous-doped Silicate Glass (BPSG), Phosphorous-doped Silicate Glass (PSG), Phosphorous-doped Tetraethylorthosilicate (PTEOS), Thermal oxide, Tetraethylorthosilicate (TEOS) oxides, Plasma Enhanced Tetraethylorthosilicate (PETEOS) oxides and high-density plasma CVD (HDPCVD) oxides can be planarized by the present slurry formulation. Silicides include tantalum silicide, titanium silicide and tungsten silicide.

Advantageously, the composition of the present invention contains 0.001 to 1 weight percent quaternary ammonium compound to enhance the removal of the dielectric layer in ILD processes. All compositions are expressed in weight percent unless specifically noted otherwise. Advantageously, the composition contains 0.01 to 0.5 weight percent quaternary ammonium compound.

The quaternary ammonium compounds of the present invention include the following structure: 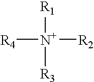
where R₁, R₂, R₃ and R₄ are an organic compound that has a carbon chain length of 1 to 15 carbon atoms. More preferably, R₁, R₂, R₃ and R₄ have a carbon chain length of 1 to 10. Most preferably, R₁, R₂, R₃ and R₄ have a carbon chain length of 1 to 5 carbon atoms. The organic compound of R₁, R₂, R₃ and R₄ may be a substituted or unsubstituted aryl, alkyl, aralkyl, or alkaryl group. Example anions include, nitrate, sulfate, halides (such as, bromide, chloride, fluoride and iodide), citrate, phosphate, oxalate, malate, gluconate, hydroxide, acetate, borate, lactate, thiocyanate, cyanate, sulfonate, silicate, per-halides (such as, perbromate, perchlorate and periodate), chromate, and mixtures comprising at least one of the foregoing anions.

Preferred quaternary ammonium compounds include, tetramethyl ammonium hydroxide, tetraethyl ammonium hydroxide, tetrapropyl ammonium hydroxide, tetraisopropyl ammonium hydroxide, tetracyclopropyl ammonium hydroxide, tetrabutyl ammonium hydroxide, tetraisobutyl ammonium hydroxide, tetratertbutyl ammonium hydroxide, tetrasecbutyl ammonium hydroxide, tetracyclobutyl ammonium hydroxide, tetrapentyl ammonium hydroxide, tetracyclopentyl ammonium hydroxide, tetrahexyl ammonium hydroxide, tetracyclohexyl ammonium hydroxide, and mixtures thereof. Most preferred quaternary ammonium compounds is tetramethyl ammonium hydroxide.

Advantageously, the polishing composition contains 0.01 to 20 weight percent abrasive to facilitate silica removal. Within this range, it is desirable to have the abrasive present in an amount of greater than or equal to 1 weight percent. Also, desirable within this range is an amount of less than or equal to 19 weight percent.

The abrasive has an average particle size between 5 to 200 nanometers (nm). For purposes of this specification, particle size refers to the average particle size of the abrasive. More preferably, it is desirable to use an abrasive having an average particle size between 20 to 150 nm. Decreasing the size of the abrasive to less than or equal to 20 nm, tends to improve the planarization of the polishing composition, but, it also tends to decrease the removal rate.

Example abrasives include inorganic oxides, inorganic hydroxides, metal borides, metal carbides, metal nitrides, polymer particles and mixtures comprising at least one of the foregoing. Suitable inorganic oxides include, for example, (colloidal) silica (SiO₂), alumina (Al₂O₃), zirconia (ZrO₂), ceria (CeO₂), manganese oxide (MnO₂), or combinations comprising at least one of the foregoing oxides. Modified forms of these inorganic oxides, such as, polymer-coated inorganic oxide particles and inorganic coated particles may also be utilized if desired. Suitable metal carbides, boride and nitrides include, for example, silicon carbide, silicon nitride, silicon carbonitride (SiCN), boron carbide, tungsten carbide, zirconium carbide, aluminum boride, tantalum carbide, titanium carbide, or combinations comprising at least one of the foregoing metal carbides, boride and nitrides. Diamond may also be utilized as an abrasive if desired. Alternative abrasives also include polymeric particles and coated polymeric particles. The preferred abrasive is colloidal silica.

Optionally, the composition advantageously contains 0 to 5 weight percent surfactant to achieve a high selectivity. Furthermore, the disclosed ranges include combining and partially combining ranges and limits within ranges. Preferably, the surfactant is 0.001 to 2 weight percent and most preferably, the surfactant is 0.01 to 1 weight percent.

A surface active agent or surfactant, as used in this specification refers to a substance that, when present, has the property of adsorbing onto the wafer substrate's surface or interfaces or alters the surface free energy of the wafer substrate's surface or interfaces. The term “interface” is a boundary between any two immiscible phases. The term “surface” denotes an interface where one phase is gas, usually air. Surfactants usually act to reduce interfacial free energy.

Anionic surfactants have a characteristic molecular structure having a structural group that has very little attraction for water known as a hydrophobic group, together with a group that has a strong attraction for water, called a hydrophilic group. The anionic surfactant has a hydrophilic group that has a negative ionic charge when it is ionized in a solution. The hydrophobic groups usually are long chain hydrocarbons, fluorocarbons or siloxane chains that have a length suitable for aqueous solubility. In particular, the hydrophobic groups have a carbon chain length of greater than three. Most advantageously, the hydrophobic group has a carbon chain length of at least six.

The preferred anionic surfactants contain a chemical group selected from at least one of carboxylate (carboxylic acid salt), sulfonate (sulfonic acid salt), sulfate (sulfuric acid salt), or phosphate (phosphoric and polyphosphoric acid ester). The hydrophilic part of the surfactant may contain one or more nitrogen atoms or one or more oxygen atoms or mixture thereof, but it contains at least one of the ionizable groups to provide solubility. The hydrophobic part of the anionic surfactants in this invention has at least five or more carbons to provide sufficient hydrophobicity. The hydrophobic portion can be either a straight chain, a branched chain or cyclic chain. The hydrophobic portion may be a saturated chain, unsaturated chain or contain an aromatic group.

Surfactants include those anionic surfactants selected from at least one of alkyl glutamates, dodececybenzenesulfonate, alkyl α-olifin sulfonates, dialkyl sulfosuccinates, alkylsulfonates, alkyl amphohydroxylypropyl sulfonates, alkylhydroxyethylimidazolines, alkyl amidopropyl betaines, methyl alkyltaurate, alkyl imidazoline and mixtures thereof. Particular surfactants include those anionic surfactants selected from at least one of methyl cocoyltaurate, dicyclohexyl sulfosuccinate (1,4-dicyclohexyl sulfonatosuccinate), dinonyl sulfosuccinate, cocoamphohydroxypropylsulfonate, C 14-17 alkyl sec sulfonate, isostearylhydroxyethylimidazoline, cocamidopropyl betaine imidazoline C8/C10, C14-16 olefin sulfonate (dodecylbenzenesulfonate), hydrogenated tallow glutamate, POE (4) oleyl ether phosphate, lauryl sulfosuccinate, dodecylbenzenesulfonate and mixtures thereof. Typically, these surfactants are added as ammonium, potassium or sodium salts. Most preferably, the surfactant is added as an ammonium salt for high-purity formulations.

Optionally, the polishing composition advantageously contains 0 to 5 weight percent of a carboxylic acid polymer to serve as a dispersant for the abrasive particles (discussed below). Preferably, the composition contains 0.05 to 1.5 weight percent of a carboxylic acid polymer. Also, the polymer preferably has a number average molecular weight of 4,000 to 1,500,000. In addition, blends of higher and lower number average molecular weight carboxylic acid polymers can be used. These carboxylic acid polymers generally are in solution but may be in an aqueous dispersion. The carboxylic acid polymer may advantageously serve as a dispersant for the abrasive particles (discussed below). The number average molecular weight of the aforementioned polymers are determined by GPC.

The carboxylic acid polymers are preferably formed from unsaturated monocarboxylic acids and unsaturated dicarboxylic acids. Typical unsaturated monocarboxylic acid monomers contain 3 to 6 carbon atoms and include acrylic acid, oligomeric acrylic acid, methacrylic acid, crotonic acid and vinyl acetic acid. Typical unsaturated dicarboxylic acids contain 4 to 8 carbon atoms and include the anhydrides thereof and are, for example, maleic acid, maleic anhydride, fumaric acid, glutaric acid, itaconic acid, itaconic anhydride, and cyclohexene dicarboxylic acid. In addition, water soluble salts of the aforementioned acids also can be used.

Particularly useful are “poly(meth)acrylic acids” having a number average molecular weight of about 1,000 to 1,500,000 preferably 3,000 to 250,000 and more preferably, 20,000 to 200,000. As used herein, the term “poly(meth)acrylic acid” is defined as polymers of acrylic acid, polymers of methacrylic acid or copolymers of acrylic acid and methacrylic acid. Blends of varying number average molecular weight poly(meth)acrylic acids are particularly preferred. In these blends or mixtures of poly(meth)acrylic acids, a lower number average molecular weight poly(meth)acrylic acid having a number average molecular weight of 1,000 to 100,000 and preferably, 4,000 to 40,000 is used in combination with a higher number average molecular weight poly(meth)acrylic acid having a number average molecular weight of 150,000 to 1,500,000, preferably, 200,000 to 300,000. Typically, the weight percent ratio of the lower number average molecular weight poly(meth)acrylic acid to the higher number average molecular weight poly(meth)acrylic acid is about 10:1 to 1:10, preferably 5:1 to 1:5, and more preferably, 3:1 to 2:3. A preferred blend comprises a poly(meth)acrylic acid having a number average molecular weight of about 20,000 and a poly(meth)acrylic acid having a number average molecular weight of about 200,000 in a 2:1 weight ratio.

In addition, carboxylic acid containing copolymers and terpolymers can be used in which the carboxylic acid component comprises 5-75% by weight of the polymer. Typical of such polymer are polymers of (meth)acrylic acid and acrylamide or methacrylamide; polymers of (meth)acrylic acid and styrene and other vinyl aromatic monomers; polymers of alkyl (meth)acrylates (esters of acrylic or methacrylic acid) and a mono or dicarboxylic acid, such as, acrylic or methacrylic acid or itaconic acid; polymers of substituted vinyl aromatic monomers having substituents, such as, halogen (i.e., chlorine, fluorine, bromine), nitro, cyano, alkoxy, haloalkyl, carboxy, amino, amino alkyl and a unsaturated mono or dicarboxylic acid and an alkyl (meth)acrylate; polymers of monethylenically unsaturated monomers containing a nitrogen ring, such as, vinyl pyridine, alkyl vinyl pyridine, vinyl butyrolactam, vinyl caprolactam, and an unsaturated mono or dicarboxylic acid; polymers of olefins, such as, propylene, isobutylene, or long chain alkyl olefins having 10 to 20 carbon atoms and an unsaturated mono or dicarboxylic acid; polymers of vinyl alcohol esters, such as, vinyl acetate and vinyl stearate or vinyl halides, such as, vinyl fluoride, vinyl chloride, vinylidene fluoride or vinyl nitriles, such as, acrylonitrile and methacrylonitrile and an unsaturated mono or dicarboxylic acid; polymers of alkyl (meth) acrylates having 1-24 carbon atoms in the alkyl group and an unsaturated monocarboxylic acid, such as, acrylic acid or methacrylic acid. These are only a few examples of the variety of polymers that can be used in the novel polishing composition of this invention. Also, it is possible to use polymers that are biodegradeable, photodegradeable or degradeable by other means. An example of such a composition that is biodegradeable is a polyacrylic acid polymer containing segments of poly(acrylate comethyl 2-cyanoacrylate).

The compounds provide efficacy over a broad pH range in solutions containing a balance of water. This solution's useful pH range extends from at least 1 to 5. In addition, the solution advantageously relies upon a balance of deionized water to limit incidental impurities. The pH of the polishing fluid of this invention is preferably from 2 to 4.5, more preferably a pH of 2 to 3. The acids used to adjust the pH of the composition of this invention are, for example, nitric acid, sulfuric acid, hydrochloric acid, phosphoric acid and the like. Exemplary bases used to adjust the pH of the composition of this invention are, for example, ammonium hydroxide and potassium hydroxide.

In addition, the solution optionally may contain a biocide for limiting biological contamination. For example, Kordek® MLX microbicide 2-Methyl-4-isothiazolin-3-one in water (Rohm and Haas Company, Philadelphia Pa.) provides an effective biocide for many applications. The biocide is typically used in the concentration prescribed by the supplier.

Accordingly, the present invention provides unexpected removal of dielectric layers and planarization efficiency with decreased concentration of abrasives. In particular, the composition comprises a quaternary ammonium compound to enhance the removal of the dielectric layer for ILD processes, at the pH of the application.

### EXAMPLE 1

This experiment measured the removal of a dielectric layer on a semiconductor wafer. In particular, the effect of quaternary ammonium compounds on removal of TEOS and planarization efficiency was tested. An IPEC 472 DE 200 mm polishing machine using an IC1000™ polyurethane polishing pad (Rohm and Haas Electronic Materials CMP Inc.) various downforce conditions and a polishing solution flow rate of 150 cc/min, a platen speed of 72 RPM and a carrier speed of 70 RPM planarized the samples. The polishing solutions had a pH of 2.5 adjusted with nitric acid. All solutions contained, by weight percent, 16 colloidal silica and balance deionized water.

TABLE 1

| | Down force | Abrasive | | TBAH | |
|---|---|---|---|---|---|
| Test | (kPA) | Wt. % | PH | Wt. % | TEOS RR (Å/min) |
| A | 13.79 | 16 | 2.5 | 0.0 | 1218 |
| 1 | 13.79 | 16 | 2.5 | 0.05 | 1425 |
| 2 | 13.79 | 16 | 2.5 | 0.1 | 1756 |
| 3 | 13.79 | 16 | 2.5 | 0.15 | 1758 |
| 4 | 13.79 | 16 | 2.5 | 0.2 | 1585 |
| 5 | 13.79 | 16 | 2.5 | 0.3 | 1659 |
| 6 | 13.79 | 16 | 2.5 | 0.4 | 1552 |

As illustrated in Table 1 above, the addition of the quaternary ammonium compound improved the removal rate of the composition. For example, the addition of the tetrabutylammonium hydroxide (TBAH) improved the removal rate of the composition of Test 1 for TEOS from 1218 Å/min (Test A) to 1425 Å/min. Also, in Test 2, an increase in the removal rate of the TEOS was observed with the addition of 0.1 wt. % of TBAH to 1756 Å/min.

### EXAMPLE 2

In this example, the down force was increased to 3 psi (20.68 kPa) to polish the samples. All other parameters were the same as those of Example 1.

TABLE 2

| | Down force | Abrasive | | TBAH | |
|---|---|---|---|---|---|
| Test | (kPa) | Wt. % | pH | Wt. % | TEOS RR (Å/min) |
| B | 20.68 | 16 | 2.5 | 0.0 | 1828 |
| 7 | 20.68 | 16 | 2.5 | 0.05 | 2391 |
| 8 | 20.68 | 16 | 2.5 | 0.1 | 2557 |
| 9 | 20.68 | 16 | 2.5 | 0.15 | 2555 |
| 10 | 20.68 | 16 | 2.5 | 0.2 | 2286 |
| 11 | 20.68 | 16 | 2.5 | 0.3 | 2352 |
| 12 | 20.68 | 16 | 2.5 | 0.4 | 2207 |

As illustrated in Table 2 above, the addition of the quaternary ammonium compound improved the removal rate of the composition. For example, the addition of the tetrabutyl ammonium hydroxide improved the removal rate of the composition of Test 7 for TEOS from 1828 Å/min (Test ) to 2391 Å/min. Also, in Test 8, an increase in the removal rate of the TEOS was observed with the addition of 0.1 wt. % of TBAH to 2557 Å/min. In addition, as illustrated by comparison to Example 1, the planarization efficiency was improved. For example, at a TBAH concentration of 0.05 weight percent, the TEOS removal rate increased to 2391 Å/min from 1425 Å/min when the down force was increased from 2 psi (13.79 kPa) to 3 psi (20.68 kPa).

### EXAMPLE 3

In this example, the down force was increased to 4 psi (27.58 kPa) to polish the samples. All other parameters were the same as those of Example 1.

TABLE 3

| | Down force | Abrasive | | TBAH | |
|---|---|---|---|---|---|
| Test | (kPa) | Wt. % | pH | Wt. % | TEOS RR (Å/min) |
| C | 27.58 | 16 | 2.5 | 0.0 | 2361 |
| 13 | 27.58 | 16 | 2.5 | 0.05 | 3175 |
| 14 | 27.58 | 16 | 2.5 | 0.1 | 3253 |
| 15 | 27.58 | 16 | 2.5 | 0.15 | 3252 |
| 16 | 27.58 | 16 | 2.5 | 0.2 | 2887 |
| 17 | 27.58 | 16 | 2.5 | 0.3 | 2942 |
| 18 | 27.58 | 16 | 2.5 | 0.4 | 2796 |

As illustrated in Table 3 above, the addition of the quaternary ammonium compound improved the removal rate of the composition. For example, the addition of the tetrabutyl ammonium hydroxide improved the removal rate of the composition of Test 13 for TEOS from 2361 (Test C) to 3175 Å/min. Also, in Test 14, an increase in the removal rate of the TEOS was observed with the addition of 0.1 wt. % of TBAH to 3253 Å/min.

### EXAMPLE 4

In this example, the down force was increased to 5 psi (34.47 kPa) to polish the samples. All other parameters were the same as those of Example 1.

TABLE 4

| | Down force | Abrasive | | TBAH | |
|---|---|---|---|---|---|
| Test | (kPa) | Wt. % | pH | Wt. % | TEOS RR (Å/min) |
| D | 34.47 | 16 | 2.5 | 0.0 | 2807 |
| 19 | 34.47 | 16 | 2.5 | 0.05 | 3732 |
| 20 | 34.47 | 16 | 2.5 | 0.1 | 3869 |
| 21 | 34.47 | 16 | 2.5 | 0.15 | 3906 |
| 22 | 34.47 | 16 | 2.5 | 0.2 | 3447 |
| 23 | 34.47 | 16 | 2.5 | 0.3 | 3499 |
| 24 | 34.47 | 16 | 2.5 | 0.4 | 3321 |

As illustrated in Table 4 above, the addition of the quaternary ammonium compound improved the removal rate of the composition. For example, the addition of the tetrabutyl ammonium hydroxide improved the removal rate of the composition of Test 19 for TEOS from 2807 (Test D) to 3732 Å/min. Also, in Test 20, an increase in the removal rate of the TEOS was observed with the addition of 0.1 wt. % of TBAH to 3869 Å/min.

### EXAMPLE 5

In this example, the down force was increased to 6 psi (41.37 kPa) to polish the samples. All other parameters were the same as those of Example 1.

TABLE 5

| | Down force | Abrasive | | TBAH | |
|---|---|---|---|---|---|
| Test | (kPa) | Wt. % | pH | Wt. % | TEOS RR (Å/min) |
| E | 41.37 | 16 | 2.5 | 0.0 | 3215 |
| 25 | 41.37 | 16 | 2.5 | 0.05 | 4260 |
| 26 | 41.37 | 16 | 2.5 | 0.1 | 4405 |
| 27 | 41.37 | 16 | 2.5 | 0.15 | 4444 |
| 28 | 41.37 | 16 | 2.5 | 0.2 | 4000 |
| 29 | 41.37 | 16 | 2.5 | 0.3 | 3999 |
| 30 | 41.37 | 16 | 2.5 | 0.4 | 3778 |

As illustrated in Table 5 above, the addition of the quaternary ammonium compound improved the removal rate of the composition. For example, the addition of the tetrabutyl ammonium hydroxide improved the removal rate of the composition of Test 25 for TEOS from 3215 Å/min (Test A) to 4260 Å/min. Also, in Test 26, an increase in the removal rate of the TEOS was observed with the addition of 0.1 wt. % of TBAH to 4405 Å/min.

### EXAMPLE 6

In this comparative example, the removal and planarization efficiency of the composition was tested without any abrasives at various down forces. All solutions contained 0.05% TBAH and a pH of 2.5 All other parameters were the same as those of Example 1.

TABLE 6

| | Down force | Abrasive | | TBAH | |
|---|---|---|---|---|---|
| Test | (kPa) | Wt. % | pH | Wt. % | TEOS RR (Å/min) |
| F | 13.79 | 0 | 2.5 | 0.05 | 7 |
| G | 20.68 | 0 | 2.5 | 0.05 | 3 |
| H | 27.58 | 0 | 2.5 | 0.05 | 0 |
| I | 34.47 | 0 | 2.5 | 0.05 | 1 |
| J | 41.37 | 0 | 2.5 | 0.05 | 2 |

As illustrated in Table 6 above, the absence of the abrasive dramatically reduced the TEOS removal rate of the composition. For example, Test F provided a TEOS removal rate of 7 Å/min even with the addition of 0.05% TBAH. An increase in down force did not materially increase the removal of the TEOS.

Accordingly, the present invention provides unexpected removal of dielectric layers utilizing decreased concentrations of abrasives. In particular, the composition comprises a quaternary ammonium compound to enhance the removal of the dielectric layer for ILD processes, at the pH of the application.

1. An aqueous composition useful for polishing dielectric layers on a semiconductor wafer in interlevel dielectric processes comprising by weight percent 0.001 to 1 quaternary ammonium compound, 0.01 to 20 colloidal silica, 0 to 5 surfactant, 0 to 5 carboxylic acid polymer, and balance water.

2. The composition of claim 1 wherein the quaternary ammonium compound is selected from the group comprising, tetramethyl ammonium hydroxide, tetraethyl ammonium hydroxide, tetrapropyl ammonium hydroxide, tetraisopropyl ammonium hydroxide, tetracyclopropyl ammonium hydroxide, tetrabutyl ammonium hydroxide, tetraisobutyl ammonium hydroxide, tetratertbutyl ammonium hydroxide, tetrasecbutyl ammonium hydroxide, tetracyclobutyl ammonium hydroxide, tetrapentyl ammonium hydroxide, tetracyclopentyl ammonium hydroxide, tetrahexyl ammonium hydroxide, tetracyclohexyl ammonium hydroxide, and mixtures thereof.

3. The composition of claim 1 wherein the quaternary ammonium compound is tetrabutyl ammonium hydroxide.

4. The composition of claim 1 wherein the composition comprises by weight percent 0.01 to 0.5 quaternary ammonium compound.

5. The composition of claim 1 wherein the carboxylic acid polymer is polyacrylic acid.

6. The composition of claim 1 wherein the surfactant is selected from the group comprising alkyl glutamates, dodececybenzenesulfonate, alkyl a-olifin sulfonates, dialkyl sulfosuccinates, alkylsulfonates, alkyl amphohydroxylypropyl sulfonates, alkylhydroxyethylimidazolines, alkyl amidopropyl betaines, methyl alkyltaurate, alkyl imidazoline and mixtures thereof.

7. The composition of claim 1 wherein the aqueous composition has a pH of 1 to 5.

8. An aqueous composition useful for polishing dielectric layers on a semiconductor wafer in interlevel dielectric processes comprising by weight percent 0.001 to 1 tetrabutyl ammonium hydroxide, 0.01 to 20 colloidal silica, 0 to 5 surfactant, 0 to 5 polyacrylic acid and balance water, wherein the composition has a pH of 2 to 5.

9. A method for polishing dielectric layers on a semiconductor wafer in interlevel dielectric processes comprising:
contacting the dielectric layers on the wafer with a polishing composition, the polishing composition comprising by weight percent 0.001 to 1 quaternary ammonium compound, 0.01 to 20 colloidal silica, 0 to 5 surfactant, 0 to 5 carboxylic acid polymer, and balance water; and
polishing the dielectric layers with a polishing pad.

10. The method of claim 9 wherein the quaternary ammonium compound is selected from the group comprising, tetramethyl ammonium hydroxide, tetraethyl ammonium hydroxide, tetrapropyl ammonium hydroxide, tetraisopropyl ammonium hydroxide, tetracyclopropyl ammonium hydroxide, tetrabutyl ammonium hydroxide, tetraisobutyl ammonium hydroxide, tetratertbutyl ammonium hydroxide, tetrasecbutyl ammonium hydroxide, tetracyclobutyl ammonium hydroxide, tetrapentyl ammonium hydroxide, tetracyclopentyl ammonium hydroxide, tetrahexyl ammonium hydroxide, tetracyclohexyl ammonium hydroxide, and mixtures thereof.
